(19) United States
(12) Patent Application Publication
(10) Pub. No.: US 2023/0314513 A1
(43) Pub. Date: Oct. 5, 2023

(54) IN-CIRCUIT EMULATOR DEVICE

(71) Applicant: LAPIS Technology Co., Ltd., Yokohama (JP)

(72) Inventor: Hiroshi YAMASAKI, Yokohama (JP)

(73) Assignee: LAPIS Technology Co., Ltd., Yokohama (JP)

(21) Appl. No.: 18/192,488

(22) Filed: Mar. 29, 2023

(30) Foreign Application Priority Data
Mar. 31, 2022 (JP) 2022-059026

(51) Int. Cl. G01R 31/319; G01R 31/317

(52) U.S. Cl. CPC G01R 31/31915; G01R 31/31726; G01R 31/31713

(57) ABSTRACT

An in-circuit emulator device includes a CPU that generates a first address signal by executing a program in synchronization with a first clock signal, a real-time capture circuit that generates a second address signal in synchronization with a second clock signal having a higher frequency than the first clock signal, and a selector circuit that supplies the second address signal to a storage device during a first period of one cycle of the first clock signal, and supplies the first address signal to the storage device during the remaining second period. The storage device reads data from a storage location of an address identified by the second address signal while the second address signal is supplied, and writes data from the CPU to a storage location of an address identified by the first address signal or reads data from said storage location while the first address signal is supplied.

### CROSS REFERENCE TO RELATED APPLICATION

This application is based upon and claims the benefit of priority of the prior Japanese Patent Application No. 2022-059026, filed on Mar. 31, 2022, the entire contents of which are incorporated herein by reference.

### TECHNICAL FIELD

The present invention relates to an in-circuit emulator device that tests a program.

### BACKGROUND ART

An in-circuit emulator is a testing device used in microcomputer system development, and checks if a program is correctly executed by a CPU of a microcomputer system or not, by emulating that CPU.

Japanese Patent Application Laid-open Publication No. 2005-182573 discloses an in-circuit emulator device that has a debugging CPU, a main memory that stores programs and data therein, a control circuit that controls the debugging CPU upon debugging, and a trace memory device that stores therein a history of commands executed when the debugging CPU is running a program, and a history of accessing data in the main memory. In this conventional in-circuit emulator device, the data newly written to the main memory as a result of executing commands in the debugging CPU can be captured and outputted from the data access history stored in the trace memory device based on the command execution history stored in the trace memory device.

### SUMMARY OF THE INVENTION

### Problems to be Solved by the Invention

However, in the conventional in-circuit emulator device, only the data written to the storage device as a result of the CPU accessing the storage device such as the main memory while the CPU is running a program is captured as the information in the data access history, and it was not possible to capture data stored in any other storage locations than the storage location of the storage device accessed by the CPU while running a program.

Thus, an object of the present invention is to provide an in-circuit emulator device that can capture data from other storage locations than the storage location accessed by the CPU while running a program.

An in-circuit emulator device of the present invention includes: a clock generation circuit that generates a first clock signal and a second clock signal having a higher frequency than a frequency of the first clock signal; a storage device that stores data; a CPU that executes a program in synchronization with the first clock signal, and generates a first address signal representing an address within the storage device to be accessed when the program is executed; a real-time capture circuit that generates a second address signal representing a pre-determined address within the storage device in synchronization with the second clock signal; and a selector circuit that receives the first address signal and the second address signal, supplies the second address signal to a storage device during a first period of one cycle of the first clock signal, and supplies the first address signal to the storage device during the remaining second period, wherein the storage device reads out data from a storage location of an address identified by the second address signal and outputs the read data to the real-time capture circuit while the second address signal is supplied from the selector circuit, and while the first address signal is supplied from the selector circuit, the storage device writes data from the CPU to a storage location of the address identified by the first address signal or reads out the data therefrom and outputs it to the CPU.

According to the in-circuit emulator device of the present invention, it is possible to acquire data from any specified storage location of the storage device regardless of the access destination of the CPU for data reading/writing, without affecting the data reading operation or data writing operation from/to the storage device by the CPU that is running a program.

### BRIEF DESCRIPTION OF THE DRAWINGS

FIG. 1 is a block diagram illustrating a configuration of an in-circuit emulator device of Embodiment 1 of the present invention.

FIG. 2 is a timing chart indicating a data reading operation of a CPU of the device illustrated in FIG. 1.

FIG. 3 is a timing chart indicating a real-time capture operation using a real-time clock signal of the device illustrated in FIG. 1.

FIG. 4 is a block diagram illustrating a configuration of an in-circuit emulator device of Embodiment 2 of the present invention.

FIG. 5 is a block diagram illustrating a configuration of an in-circuit emulator device of Embodiment 3 of the present invention.

### DETAILED DESCRIPTION OF EMBODIMENTS

Below, embodiments of the present invention will be explained in detail with reference to figures.

### Embodiment 1

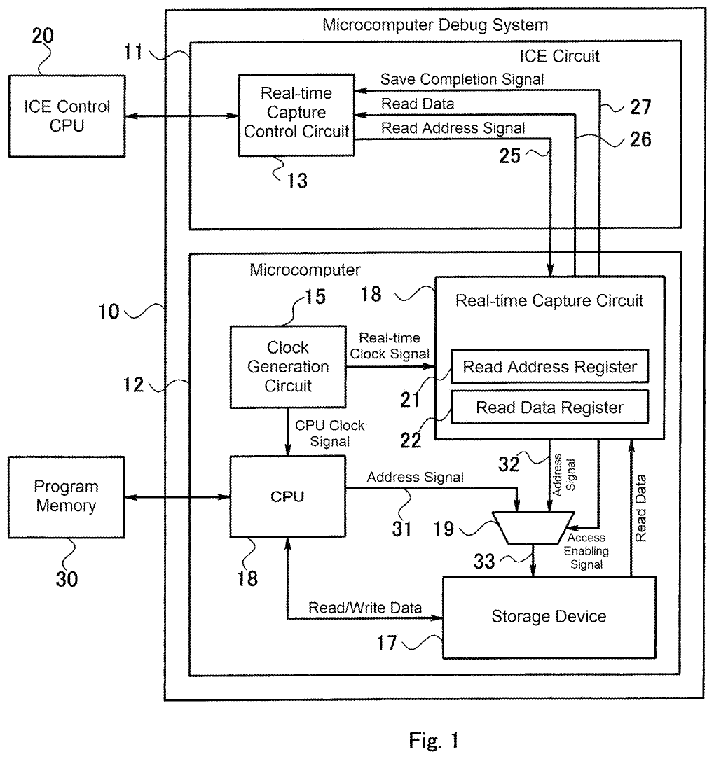

FIG. 1 illustrates the configuration of an in-circuit emulator device of Embodiment 1 of the present invention. This in-circuit emulator device is provided with a microcomputer debug system 10 including an ICE (in-circuit emulator) circuit 11 and a microcomputer 12, an ICE control CPU (central processing unit) 20 and a program memory 30.

The ICE circuit 11 includes a real-time capture control circuit 13. The microcomputer 12 includes a clock generation circuit 15, a CPU 16, a storage device 17, a real-time capture circuit 18, and a selector circuit 19. The real-time capture circuit 18 has a read address register 21 and a read data register 22.

The ICE control CPU 20 is connected to the real-time capture control circuit 13 to send commands to the real-time capture control circuit 13 and receive data outputted from the real-time capture control circuit 13. The real-time capture circuit 13 is connected to the real-time capture circuit 18. There are an address line 25, a data line 26, and a signal line 27 between the real-time capture control circuit 13 and the real-time capture circuit 18.

In the microcomputer 12, the clock generation circuit 15 generates a CPU clock signal (first clock signal) and a real-time clock signal (second clock signal). The CPU clock signal is supplied to the CPU 16, determining the operation timing of the CPU 16. In Embodiment 1, the real-time clock signal has a frequency that is twice as high as the frequency of the CPU clock signal. The real-time clock signal rises at the same time as the CPU clock signal. The real-time clock signal is supplied to the real-time capture circuit 18, determining the operation timing of the real-time capture circuit 18.

The real-time capture circuit 18 supplies to the real-time capture control circuit 13 a hold/save completion signal and read data. The real-time capture circuit 18 reads out an address identified by the read address signal supplied from the real-time capture control circuit 13, and stores the address in the read address register 21.

The CPU 16 is connected to the program memory 30. The program memory 30 has stored therein a program for debugging. The CPU 16 executes the program for debugging stored in the program memory 30. In executing the program, the CPU 16 specifies execution addresses (program execution addresses) of the program memory 30 successively, and commands of the program for debugging are read from the storage location specified by the execution address. The CPU 16 then executes the read-out commands.

Also, the CPU 16 supplies an address signal (first address signal) from its own address output terminal to the selector circuit 19 via an address line 31, and the real-time capture circuit 18 supplies an address signal (second address signal) from its own address output terminal via an address line 32 to the selector circuit 19. The address lines 31 and 32 are connected to the selector circuit 19. The selector circuit 19 is connected to the storage device 17 via an address line 33, selects one of the address signal from the CPU 16 and the address signal from the real-time capture circuit 18 based on an access enabling signal supplied from the real-time capture circuit 18, and supplies the selected address signal to the storage device 17 via the address line 33.

The access enabling signal is a signal that becomes active (high-level, for example) only during one cycle of the real-time clock signal when the real-time capture circuit 18 specifies addresses in the storage device 17 to read out data. The access enabling signal stays inactive (low-level, for example) during any other cycles.

The storage device 17 includes a data memory (not shown) such as a RAM (random access memory) in which data is stored when the CPU 16 executes a program for debugging, and a peripheral circuit register (not shown) for temporarily storing data, and is configured such that the storage location is specified by the address identified by the supplied address signal. The storage device 17 writes the data supplied from the CPU 16 via a data line 34 to a storage location specified by the address identified by the address signal, or reads out the written data and outputs it to the data line 34 as a signal. The data line 34 is connected to the data input/output terminals of the CPU 16 and the data input terminal of the real-time capture circuit 18.

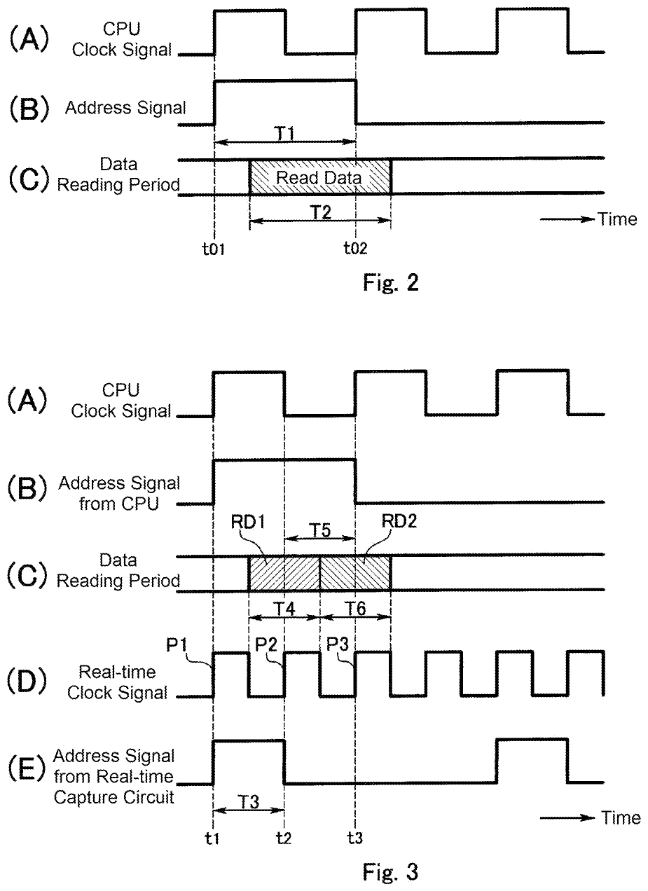

In the in-circuit emulator device having this configuration, the clock generation circuit 15 generates a CPU clock signal having a waveform illustrated in FIG. 2A. When the CPU clock signal rises at t01, the CPU 16 generates an address signal. This address signal specifies an address during one period T1 of the CPU clock signal as illustrated in FIG. 2B. The address is a value specifying one storage location of all the storage locations in the storage device 17. The address signal is supplied to the storage device 17 via the address line 31, the selector circuit 19, and the address line 33. When the CPU 16 reads out data from the storage device 17 while executing the program for debugging stored in the program memory 30, data is read out from a storage location of the storage device 17 corresponding to the address identified by the address signal at the timing illustrated in FIG. 2C. The read data is continuously outputted during the period T2, and captured by the CPU 16 when the CPU clock signal rises next, i.e., t02. The length of the period T2 is equal to the length of the period T1 of the CPU clock signal.

In the data reading operation illustrated in FIG. 2, the access enabling signal stays inactive (low-level, for example), and the selector circuit 19 supplies the address signal outputted from the CPU 16 to the storage device 17.

Next, the real-time capture operation of the in-circuit emulator device will be explained with reference to the timing charts of FIGS. 3A to 3E.

The clock generation circuit 15 generates a CPU clock signal having a waveform as illustrated in FIG. 3A, and generates a real-time clock signal having a waveform as illustrated in FIG. 3D. As described above, the real-time clock signal has a frequency that is twice as high as the frequency of the CPU clock signal. When the CPU clock signal rises at t1, the CPU 16 generates an address signal as illustrated in FIG. 3B. This is the same as FIG. 2B.

Assuming that the ICE control CPU 20 generates a real-time capture command to the real-time capture control circuit 13 after the CPU 16 started executing the program for debugging, the real-time capture command includes an address that specifies a storage location of the storage device 17 from which data is to be read. When the real-time capture command is supplied to the real-time capture control circuit 13, the real-time capture control circuit 13 outputs to the real-time capture circuit 18 a read address signal indicating the address identified by the real-time capture command. The read address signal is supplied to the real-time capture circuit 18 via the address line 25. Upon receiving the read address signal, the real-time capture circuit 18 reads an address identified by the address signal, and writes the address to the read address register 21.

Thereafter, the real-time capture circuit 18 reads an address from the read address register 21 when a pulse P1 of the real-time clock signal rises at t1, and generates an address signal indicating that address. The address signal continues to be generated over the period T3 (first period) illustrated in FIG. 3E. The period T3 is a length of time between the rise of the pulse P1 of the real-time clock signal and the rise of the next pulse P2, i.e., t2.

The real-time capture circuit 18 activates the access enabling signal at the same time as generating the address signal. As a result, the selector circuit 19 supplies the address signal outputted from the real-time capture circuit 18 to the storage device 17. That is, the address signal outputted from the real-time capture circuit 18 is supplied to the storage device 17 via the address line 32, the selector circuit 19, and the address line 33.

In the storage device 17, data RD1 is read from a storage location corresponding to the address identified by the supplied address signal. The read data RD1 is read within the period T4 illustrated in FIG. 3C. That is, the period T4 is a duration between the time at which the pulse P1 of the real-time clock signal drops and the time at which the next pulse P2 drops. The read data RD1 is supplied to the real-time capture circuit 18 from the storage device 17, and captured.

The real-time capture circuit 18 stores the captured read data RD1 in the read data register 22. Immediately after the read data RD1 is stored, the real-time capture circuit 18 activates a save completion signal, and supplies the signal to the real-time capture control circuit 13 via the signal line 27.

Upon detecting that the save completion signal being activated via the real-time capture control circuit 13, the ICE control CPU 20 acquires the read data RD1 from the storage location of the storage device 17 corresponding to the address specified by the real-time capture command via the real-time capture control circuit 13.

The access enabling signal becomes inactive after the period T3, and the selector circuit 19 supplies the address signal outputted from the CPU 16 to the storage device 17 as illustrated in FIG. 3B. The address signal outputted from the CPU 16 continues to be supplied to the storage device 17 during the period T5 (second period) as illustrated in FIG. 3B. The period T5 is a duration between the time at which the pulse P2 of the real-time clock signal rises and the time at which the next pulse P3 rises.

As a result, data RD2 is read from the storage location of the storage device 17 corresponding to the address identified by the address signal. The read data RD2 is continuously outputted from the storage device 17 over the period T6, and captured by the CPU 16 when the CPU clock signal rises next, i.e., t3. The period T6 is a duration between the time at which the pulse P2 of the real-time clock signal drops and the time at which the next pulse P3 drops.

As described above, in the in-circuit emulator device of Embodiment 1, data RD1 is read from the storage location in the storage device 17 corresponding to the address stored in the read address register 21 in the first half of one cycle of the CPU clock signal, and the read data RD1 is stored in the read data register 22 of the real-time capture circuit 18, and then supplied to the ICE control CPU 20 via the real-time capture control circuit 13. In the second half of one cycle of the CPU clock signal, data RD2 is read from the storage location of the storage device 17 corresponding to the address identified by the address signal outputted from the CPU 16, and the read data RD2 is supplied to the CPU 16.

Thus, in the in-circuit emulator device of Embodiment 1, it is possible to acquire data from any specified storage location of the storage device 17 regardless of the access destination of the CPU 16 for data reading, without affecting the data reading operation from the storage device 17 performed by the CPU 16 while running a program for debugging. The ICE control CPU 20 can display the data from the specified storage location of the storage device 17 in real-time by supplying the data acquired via the real-time capture control circuit 13 to a not-shown display device.

In Embodiment 1 described above, in the second half of one cycle of the CPU clock signal, the data reading operation is performed to read data from the storage location of the storage device 17 corresponding to the address identified by the address signal outputted from the CPU 16, but it is also possible to write data to the storage location of the storage device 17 corresponding to the address identified by the address signal outputted from the CPU 16.

In addition, in Embodiment 1 described above, the frequency of the real-time clock signal is set to be twice as high as the frequency of the CPU clock signal, but the present invention is not limited to such. The frequency of the real-time clock signal simply needs to be higher than the frequency of the CPU clock signal.

### Embodiment 2

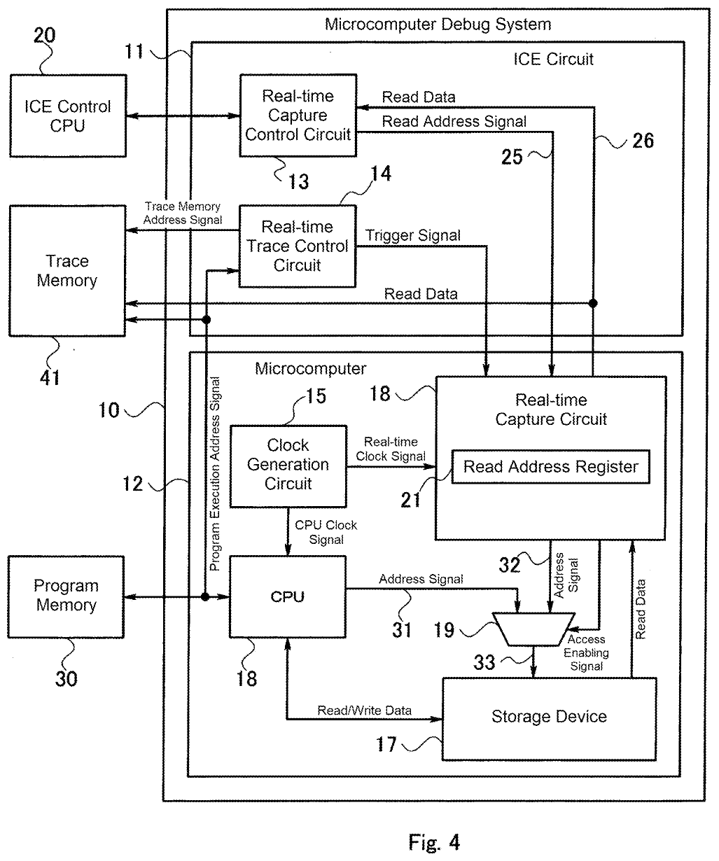

FIG. 4 illustrates the configuration of an in-circuit emulator device of Embodiment 2 of the present invention. In the in-circuit emulator device of Embodiment 2, the ICE circuit 11 includes a real-time trace control circuit 14 in addition to the real-time capture control circuit 13. The real-time trace control circuit 14 is connected to the real-time capture circuit 18, and generates a trigger signal for the real-time capture circuit 18 after the CPU 16 started executing the program for debugging. The trigger signal is generated when a program executing address signal outputted from the CPU 16 for the program memory 30 indicates a predetermined address.

The real-time capture circuit 18 in the microcomputer 12 has a read address register 21, but does not have the read data register 22, unlike Embodiment 1. In addition, the address line 25 and the data line 26 are provided between the real-time capture control circuit 13 and the real-time capture circuit 18, but the signal line 27 is not provided.

Furthermore, the in-circuit emulator device of Embodiment 2 also includes a trace memory 41 in addition to the ICE control CPU 20 and the program memory 30 outside the microcomputer debug system 10. The trace memory 41 is connected to the real-time trace control circuit 14, the real-time capture circuit 18, and the program memory 30, and under the control of the real-time trace control circuit 14, receives data read from a storage location of the storage device 17 corresponding to an address stored in the read address register 21 via the real-time capture circuit 18, and stores the data in sequence together with a program execution address of the program memory 30 to formulate trace history data.

Other configurations of the in-circuit emulator device of Embodiment 2 are similar to those of the in-circuit emulator device of Embodiment 1, and thus the descriptions thereof will not be repeated.

Next, the operation of the in-circuit emulator device of Embodiment 2 will be explained.

First, assuming that the ICE control CPU 20 generates a real-time capture command to the real-time capture control circuit 13 after the CPU 16 started executing the program for debugging, when the real-time capture command is supplied to the real-time capture control circuit 13, the real-time capture control circuit 13 outputs to the real-time capture circuit 18 a read address signal indicating addresses for tracing, which are included in the real-time capture command. The read address signal is supplied to the real-time capture circuit via the address line 25. Upon receiving the read address signal, the real-time capture circuit 18 reads an address identified by the address signal, and writes the address to the read address register 21. Then, when the real-time trace control circuit 14 outputs the trigger signal to the real-time capture circuit 18 while the CPU 16 is executing the program for debugging, data is read from the storage location of the storage device 17 corresponding to the address stored in the read address register 21 in the first half of one cycle of the CPU clock signal in a manner similar to Embodiment 1.

The read data is supplied to the real-time capture control circuit 13 as well as the trace memory 41 via the real-time capture circuit 18. The trace memory 41 receives a counter value of a trace counter (not shown) within the real-time trace control circuit 14 as a trace memory address signal, and the read data is stored in the storage location specified by the counter value together with the program execution address. Since the counter value of the trace counter increases as the program commands progress, the read data and the program execution address are stored in sequence in the storage location of the trace memory 41 corresponding to the increased count value.

As described above, in the in-circuit emulator device of Embodiment 2, data is read from the storage location of the storage device 17 corresponding to the address stored in the read address register 21 in the first half of one cycle of the CPU clock signal, and the read data is stored in the trace memory 41 in sequence via the real-time capture circuit 18. In the second half of one cycle of the CPU clock signal, data is read from the storage location of the storage device 17 corresponding to the address identified by the address signal outputted from the CPU 16, and the read data is supplied to the CPU 16.

Thus, in the in-circuit emulator device of Embodiment 2, it is possible to trace data from any specified storage location of the storage device 17 regardless of the access destination of the CPU 16 for data reading, without affecting the data reading operation from the storage device 17 performed by the CPU 16 while running a program for debugging.

In Embodiment 2, it is also possible to provide a comparator in the real-time capture circuit 18 to compare the current value of read data and the previous value of read data, so that only when the read data changes, the counter value of the trace counter is updated, and the read data is written to the trace memory 41. This makes it possible to save the storage capacity of the trace memory 41.

### Embodiment 3

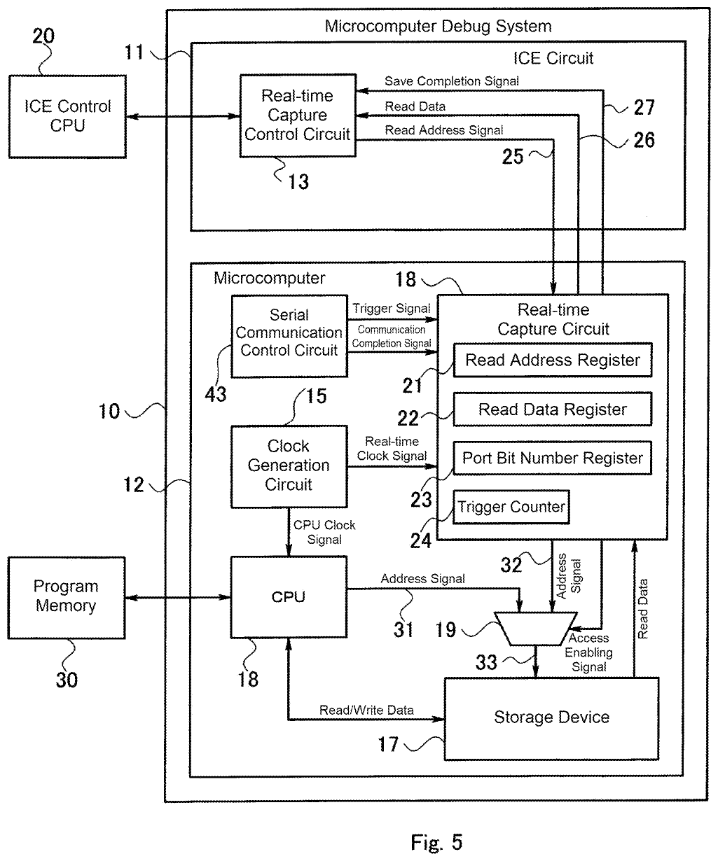

FIG. 5 illustrates the configuration of an in-circuit emulator device of Embodiment 3 of the present invention. In the in-circuit emulator device of Embodiment 3, the microcomputer 12 includes a serial communication control circuit 43 that controls serial communication while the CPU 16 is executing a program. The real-time capture circuit 18 includes a port bit number register 23 and a trigger counter 24 in addition to the read address register 21 and the read data register 22. The address of the port used by the serial communication control circuit 43 for the serial communication control is written to the read address register 21, and the port bit number is written to the port bit number register 23. This writing operation is controlled by the real-time capture control circuit 13. The storage device 17 has a communication port. The trigger counter 24 counts the number of generated trigger signals, which will be described later.

The serial communication control circuit 43 is connected to the real-time capture circuit 18, and outputs a trigger signal and a communication complete signal to the real-time capture circuit 18. The trigger signal may be a communication clock if the serial communication control circuit 43 performs synchronous communication, and may be a clock for serial communication such as the Baud rate clock if the serial communication control circuit 43 performs asynchronous communication.

Other configurations of the in-circuit emulator device of Embodiment 3 are similar to those of the in-circuit emulator of Embodiment 1, and thus the descriptions thereof will not be repeated.

Next, the operation of the in-circuit emulator device of Embodiment 3 will be explained.

First, before the CPU 16 starts executing a program, the real-time capture control circuit 13 outputs a read address signal to the real-time capture circuit 18 in accordance with a command from the ICE control CPU 20. The real-time capture circuit 18 writes the address of the port to be used by the serial communication control circuit 43, which is identified by the read address signal, to the read address register 21, and writes the port bit number identified by the read address signal to the port bit number register 23.

After the CPU 16 starts executing the program for debugging, the serial communication control circuit 43 outputs a trigger signal, and the real-time capture circuit 18 reads out the address of the port to be used from the read address register 21 according to the real-time clock signal outputted by the clock generation circuit 15, and reads out the data corresponding to the read port address from the storage device 17. The real-time capture circuit 18 then extracts bit data of the effective bit from the read data identified by the bit number stored in the port bit number register 23, and writes the extracted bit data to the read data register 22 in the real-time capture circuit 18. The writing operation of the extracted bit data is linked to the counter value of the trigger counter 24 that counts the number of generated trigger signals.

The serial communication control circuit 43 generates a communication completion signal when serial communication is completed, and supplies the communication completion signal to the real-time capture circuit 18. In response to the communication completion signal, the real-time capture circuit 18 ends the data writing to the read data register 22, activates the save completion signal, and supplies the save completion signal to the real-time capture control circuit 13 via the signal line 27.

Upon detecting that the save completion signal being activated via the real-time capture control circuit 13, the ICE control CPU 20 reads out the bit data corresponding to the port address used by the serial communication control circuit 43, which was extracted through the generation of the trigger signal, from the read data register 22 via the real-time capture control circuit 13, and acquires the bit data via the data line 26 and the real-time capture control circuit 13.

As described above, in the in-circuit emulator device of Embodiment 3, data is read from the storage location in the storage device 17 corresponding to the communication port address stored in the read address register 21 in the first half of one cycle of the CPU clock signal. From the read data, bit data for the port bit number is extracted, and the bit data is first stored in the read data register 22 of the real-time capture circuit 18, and then supplied to the ICE control CPU 20 via the real-time capture control circuit 13. In the second half of one cycle of the CPU clock signal, data is read from the storage location of the storage device 17 corresponding to the address identified by the address signal outputted from the CPU 16, and the read data is supplied to the CPU 16.

Thus, in the in-circuit emulator device of Embodiment 3, it is possible to acquire bit data of received data or transmitted data for every serial communication clock or Baud rate clock from any specified storage locations of the storage device 17 regardless of the access destination of the CPU 16 for data reading, without affecting the data reading operation from the storage device 17 performed by the CPU 16 while running a program for debugging.

In Embodiment 3, an example was explained in which the trigger signal supplied to the real-time capture circuit 18 was used for the serial communication clock, but by applying interrupts per time unit such as one-second interrupts to the trigger signal, it is possible to acquire data of a specified address at prescribed time intervals.

In the embodiments described above, the frequency of the real-time clock signal is set to be twice as high as the frequency of the CPU clock signal, but in the in-circuit emulator device of the present invention, the frequency of the real-time clock signal may be set to any frequency as long as it is higher than the frequency of the CPU clock signal.

What is claimed is:

1. An in-circuit emulator device, comprising:
a clock generation circuit that generates a first clock signal and a second clock signal that has a higher frequency than a frequency of the first clock signal;
a storage device that stores data;
a central processing unit (CPU) that executes a program in synchronization with the first clock signal, and generates a first address signal specifying an address within the storage device to be accessed when the program is executed;
a real-time capture circuit that generates a second address signal specifying a predetermined address within the storage device in synchronization with the second clock signal; and
a selector circuit that receives the first address signal and the second address signal, supplies the second address signal to a storage device during a first period of one cycle of the first clock signal, and supplies the first address signal to the storage device during a remaining second period,
wherein the storage device reads out data from a storage location corresponding to an address identified by the second address signal and outputs the read data to the real-time capture circuit while the second address signal is supplied from the selector circuit, and
while the first address signal is supplied from the selector circuit, the storage device writes data from the CPU to a storage location corresponding to an address identified by the first address signal or reads out data from the storage location corresponding to the address identified by the first address signal and outputs the data read out from the storage location corresponding to the address identified by the first address signal to the CPU.

2. The in-circuit emulator device according to claim 1,
wherein the frequency of the second clock signal is twice as high as the frequency of the first clock signal, and the first period and the second period each correspond to one cycle of the second clock signal.

3. The in-circuit emulator device according to claim 1, wherein the real-time capture circuit includes a read address register that stores therein the address identified by the second address signal, and a read data register that stores data read out from the storage location of the storage device corresponding to the address identified by the second address signal.

4. The in-circuit emulator device according to claim 3, further comprising a real-time capture control circuit that reads out data from the read data register every time data is saved in the read data register.

5. The in-circuit emulator device according to claim 1, further comprising a trace memory; and
a real-time trace control circuit that writes to the trace memory the read data outputted to the real-time capture circuit in sequence while specifying a storage location.

6. The in-circuit emulator device according to claim 5, further comprising a program memory that stores the program,
wherein the real-time trace control circuit generates a trigger signal in accordance with a program execution address signal that is outputted from the CPU and that indicates a storage location of the program memory, and
wherein the real-time capture circuit generates the second address signal in response to the trigger signal.

7. The in-circuit emulator device according to claim 3, wherein the read address register stores an address of a communication port as an address of a predetermined storage location in the storage device,
wherein the real-time capture circuit further includes a port bit number register that stores therein a port bit number of the communication port, and
wherein, upon generating the second address signal, the real-time capture circuit reads out data from a storage location of the storage device corresponding to the communication port address stored in the read address register, extracts bit data for the port bit number stored in the port bit number register from the read data, and saves the bit data in the read data register.

8. The in-circuit emulator device according to claim 7, further comprising a serial communication control circuit that generates a trigger signal in synchronization with a serial communication clock, and generates a communication completion signal after serial communication is completed,
wherein the real-time capture circuit generates the second address signal in response to the trigger signal, and stops saving the bit data in the read data register in response to the communication completion signal.
